(19) United States
(12) Patent Application Publication
(10) Pub. No.: US 2024/0234352 A9
(43) Pub. Date: Jul. 11, 2024

(54) STACKED CHIP AND FABRICATION METHOD OF STACKED CHIP

(71) Applicants: ADVANTEST CORPORATION, Tokyo (JP); Tokyo Institute of Technology, Tokyo (JP)

(72) Inventors: Shinji SUGATANI, Saitama (JP); Takayuki OHBA, Kanagawa (JP); Norio CHUJO, Tokyo (JP); Koji SAKUI, Tokyo (JP); Tadashi FUKUDA, Tokyo (JP)

(21) Appl. No.: 18/450,435

(22) Filed: Aug. 16, 2023

(30) Foreign Application Priority Data
Oct. 25, 2022 (JP) 2022-171014

(51) Int. Cl. H01L 23/00; H01L 21/768; H01L 23/48; H01L 23/522

(52) U.S. Cl. CPC H01L 24/08; H01L 21/76898; H01L 23/481; H01L 23/5226; H01L 24/80; H01L 2224/08145; H01L 2224/80895; H01L 2224/80896

(57) ABSTRACT

A stacked chip is provided comprising a first semiconductor chip and a second semiconductor chip, wherein the first semiconductor chip has a first supporting substrate and a first circuit layer including a first region in which a first circuit is formed and a second region in which a second circuit is formed, the second semiconductor chip has a second supporting substrate, a second circuit layer including a third region that corresponds to a position of the first region and a fourth region that corresponds to a position of the second region and in which the second circuit is formed, a first embedded portion embedded in a first hole portion penetrating through the third region and extending to an inside of the second supporting substrate, and a first through via that penetrates through the first embedded portion and the second supporting substrate, and is electrically conducted with the first circuit.

The contents of the following patent application(s) are incorporated herein by reference:
NO. 2022-171014 filed in JP on Oct. 25, 2022

### BACKGROUND

### 1. Technical Field

The present invention relates to a stacked chip and a fabrication method of the stacked chip.

### 2. Related Art

Patent document 1 describes that “A stacked element has a structure in which an external interface element and a plurality of internal elements stacked thereon are stacked . . . the internal elements may be identical elements or may be different types of semiconductor elements” (paragraph 0016). Patent document 2 describes that “Terminals of the chip selection signal (CE) are overlapped in one vertical line when the through electrodes 14 can only be formed in the vertical direction and identical semiconductor elements are stacked” (paragraph 0003). Patent document 3 describes that “the semiconductor chip 110 and the semiconductor chip 210 are bonded via a resin layer 160 that is an insulating layer, and the electrode pad 150 of the semiconductor chip 110 and the electrode pad 250 of the semiconductor chip 210 are electrically connected via a metal layer 380 filled in the via hole 210y” (paragraph 0016).

### PRIOR ART LITERATURE

### Patent Document

Patent Document 1: Japanese Patent Application Publication No. 2014-86498
Patent Document 2: Japanese Patent Application Publication No. 2007-250561
Patent Document 3: WO 2012/120659

### BRIEF DESCRIPTION OF THE DRAWINGS

FIG. 1 is a schematic configuration diagram of a stacked chip 10 according to a first embodiment.

FIG. 2 is a schematic cross-sectional view of the stacked chip 10 according to the first embodiment.

FIG. 3 is a schematic cross-sectional view illustrating an example of a fabrication method of the stacked chip 10 according to the first embodiment.

FIG. 4 is a schematic cross-sectional view illustrating an example of a fabrication method of the stacked chip 10 according to the first embodiment.

FIG. 5 is a schematic cross-sectional view illustrating an example of a fabrication method of the stacked chip 10 according to the first embodiment.

FIG. 6 is a schematic cross-sectional view illustrating an example of a fabrication method of the stacked chip 10 according to the first embodiment.

FIG. 7 is a schematic cross-sectional view illustrating an example of a fabrication method of the stacked chip 10 according to the first embodiment.

FIG. 8 is a schematic cross-sectional view illustrating an example of a fabrication method of the stacked chip 10 according to the first embodiment.

FIG. 9 is a schematic cross-sectional view illustrating an example of a fabrication method of the stacked chip 10 according to the first embodiment.

FIG. 10 is a schematic cross-sectional view illustrating an example of a fabrication method of the stacked chip 10 according to the first embodiment.

FIG. 11 is a schematic cross-sectional view illustrating an example of a fabrication method of a stacked chip 20 according to a second embodiment.

FIG. 12 is a schematic cross-sectional view illustrating an example of a fabrication method of a stacked chip 30 according to a third embodiment.

FIG. 13 is a schematic cross-sectional view illustrating an example of a fabrication method of a stacked chip 40 according to a fourth embodiment.

### DESCRIPTION OF EXEMPLARY EMBODIMENTS

Hereinafter, embodiments of the present invention will be described. However, the following embodiments are not for limiting the invention according to the claims. In addition, not all combinations of features described in the embodiments are essential to the solution of the invention.

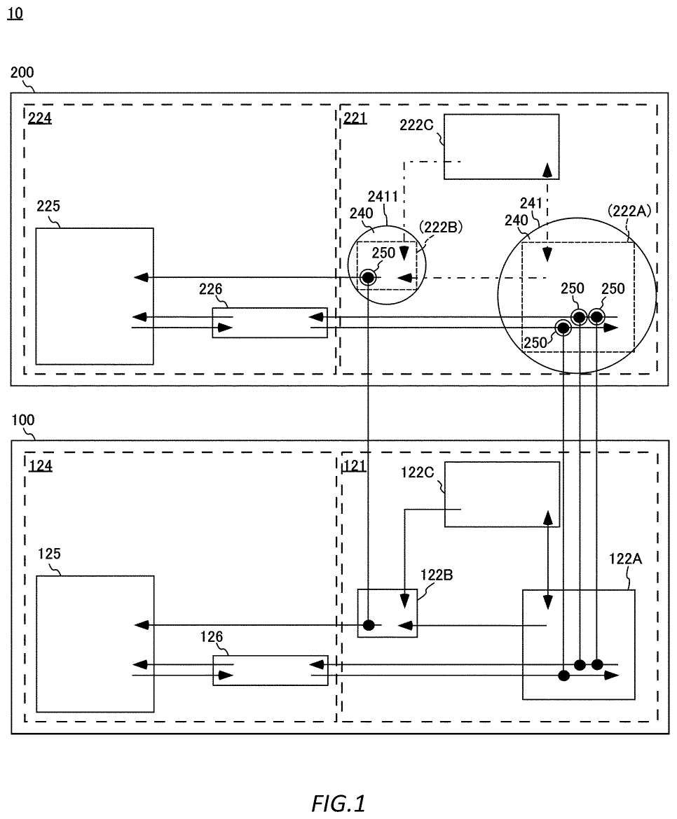

FIG. 1 is a schematic configuration diagram of a stacked chip 10 according to a first embodiment. In FIG. 1, the plurality of circuits are connected with a schematic signal line, and the flow of the signal in the signal line is illustrated with an arrow. Also in FIG. 1, circuits that have been destroyed and removed is illustrated with dashed lines, and the signal line through which signals do not flow due to being destroyed and removed is illustrated with dashed-dotted lines. Also in FIG. 1, a plurality of regions are illustrated with a dashed box, which will be similarly illustrated in the following figures.

The stacked chip 10 includes a first semiconductor chip 100 and a second semiconductor chip 200. The stacked chip 10 is a stacked-type dynamic memory, for example, in which the second semiconductor chip 200 is bonded to the first semiconductor chip 100.

In the first embodiment, the first semiconductor chip 100 is a master memory die, and the second semiconductor chip 200 is a slave memory die. The first semiconductor chip 100 that is the master memory die inputs/outputs a signal with the outside of the stacked chip 10, and controls the entire stacked chip 10. The second semiconductor chip 200 that is the slave memory die is not connected to the outside of the stacked chip 10, and inputs/outputs a signal with the stacked first semiconductor chip 100 via a TSV (through silicon via, a silicon-through electrode). The second semiconductor chip 200 is controlled by the first semiconductor chip 100.

The first semiconductor chip 100 has a first region 121 in which a first circuit 122 is formed, and a second region 124 in which a second circuit 125 is formed. The first circuit 122 is a control circuit and the second circuit 125 is a memory circuit. In the configuration example illustrated in FIG. 1, a first circuit 122A, a first circuit 122B, and a first circuit 122C are formed in the first region 121, and a second circuit 125 and a data path 126 are formed in the second region 124.

As an example, the first circuit 122A is a interface circuit, the first circuit 122B is a decoding circuit, and the first circuit 122C is a configuration register circuit. The first circuit 122A that is the interface circuit may input a clock (CK) signal or a command address (C/A) signal from the outside of the stacked chip 10, and may input/output a strobe (DQS) signal or data with the outside of the stacked chip 10. The first circuit 122A inputs these signals to the first circuit 122B, the first circuit 122C, and the data path 126. The first circuit 122A reads the signal from the second circuit 125 via the data path 126.

The first circuit 122B that is the decoding circuit decodes the signal input from the first circuit 122A, and causes the same to be stored in the second circuit 125. The first circuit 122C that is the configuration register circuit stores the setting for the first circuit 122A and the first circuit 122B, and reads the setting from the first circuit 122A and the first circuit 122B.

The second circuit 125 stores a signal input from the first circuit 122B. The data path 126 may include a circuit that performs a predetermined arithmetic processing, such as an adder or a multiplier, for example. The data path 126 may perform the predetermined operation on the signal read from the second circuit 125 in accordance with the instruction input from the first circuit 122A, for example, and output the result to the first circuit 122A.

The second semiconductor chip 200 that is the slave memory die is formed from a semiconductor chip having the same circuit configuration, that is fabricated at the same fabrication line as the first semiconductor chip 100, for example. That is, a semiconductor chip that is a precursor of the second semiconductor chip 200 has a third region 221 on which the first circuit 222 is formed, and a fourth region 224 on which the second circuit 225 is formed, similarly to the first semiconductor chip 100. The first circuit 222 is a control circuit, and the second circuit 225 is a memory circuit. In the configuration example illustrated in FIG. 1, a first circuit 222A, a first circuit 2228, and a first circuit 222C are formed in the third region 221, and a second circuit 225 and a data path 226 is formed in the fourth region 224.

Since the second semiconductor chip 200 is controlled by the first semiconductor chip 100, the first circuit 222 that is a control circuit specific to the master memory die is not required. Therefore, the stacked chip 10 destroys and removes at least any of the one or more first circuit 222 in the semiconductor chip that is a precursor of the second semiconductor chip 200, and the region after the destroying and removing is utilized as a region for TSV to cause input/output of a signal between the first semiconductor chip 100 and the second semiconductor chip 200.

Specifically, the second semiconductor chip 200 has a first embedded portion 240 embedded in a first hole portion 241 that has been formed by destroying and removing the first circuit 222A that is the interface circuit and the first circuit 2228 that is the decoding circuit in the semiconductor chip that is a precursor, as an example, and one or more first through vias 250 formed on the first embedded portion 240. In other words, the second semiconductor chip 200 has the first embedded portion 240 and the first through via 250 instead of the first circuit 222A and the first circuit 2228 among the first circuit 222. Note that, the first through via 250 corresponds to the TSV described above.

A signal is input to the second circuit 225 and the data path 226 of the second semiconductor chip 200 from the first circuit 122 of the first semiconductor chip 100 via the first through via 250. Specifically, the second circuit 225 stores the signal input from the first circuit 122B of the first semiconductor chip 100. The data path 226 may comprise a configuration that is similar to that of the data path 126, and may perform a predetermined operation on the signal read from the second circuit 225, in accordance with the instruction input from the first circuit 122A of the first semiconductor chip 100, for example, and output the result to the first circuit 122A of the first semiconductor chip 100.

In the stacked chip 10 comprising such a configuration, the first circuit 122 of the first semiconductor chip 100 inputs/outputs a signal or relays a signal between the second circuit 125 of the first semiconductor chip 100 and the second circuit 225 of the second semiconductor chip 200 and the outside of the stacked chip 10. The first circuit 122 of the first semiconductor chip 100 may read signals from the second circuit 125 and the second circuit 225 in parallel, perform serial conversion thereto and output the result to the outside.

Note that, in the configuration example illustrated in FIG. 1, although it has been described that the second semiconductor chip 200 destroys and removes the first circuit 222A and the first circuit 222B in the semiconductor chip that is the precursor to set the region as the TSV region, it may destroy and remove any one or more of the first circuit 222A, the first circuit 222B, and the first circuit 222C in the semiconductor chip that is the precursor to set the region as the TSV region, or instead or in addition to these, may destroy and remove one or more first circuit 222 of other types to set the region as the TSV region. The first semiconductor chip 100 and the second semiconductor chip 200 may have the same structure, except that the second semiconductor chip 200 does not have the first circuit 222 in the third region 221.

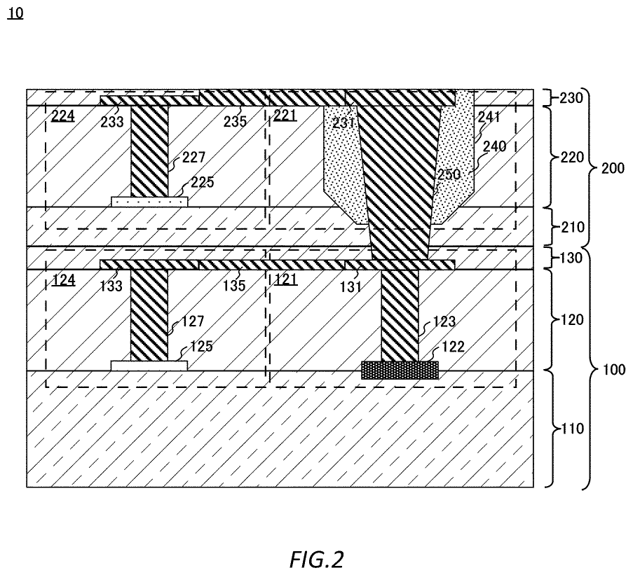

FIG. 2 is a schematic cross-sectional view of the stacked chip 10 according to the first embodiment. As illustrated in FIG. 2, the stacked chip 10 has a structure in which the second semiconductor chip 200 is stacked on the first semiconductor chip 100.

The first semiconductor chip 100 has a first supporting substrate 110, a first circuit layer 120, and a first rewiring layer 130. The first supporting substrate 110 is a silicon substrate, for example, and has a thickness of approximately 200 μm.

The first circuit layer 120 is formed on the first supporting substrate 110. The first circuit layer 120 includes the first region 121 on which the first circuit 122 is formed and the second region 124 on which the second circuit 125 is formed, described above. The first circuit layer 120 further includes a first via 123 and a second via 127 formed with a conductive material such as copper. The first circuit layer 120 is formed by depositing an insulative material such as silicon on the first supporting substrate 110, excluding the first circuit 122 or the metal element such as the first via 123, and has a thickness of approximately 5 to 50 μm. Note that, the first circuit layer 120 may be bonded to the first supporting substrate 110 via an adhesive layer.

The first circuit 122 and the second circuit 125 are each formed on the first supporting substrate 110. The first circuit 122 may include a PMOS and an NMOS formed near the surface of the first supporting substrate 110, for example, and a gate electrode formed on the surface of the first supporting substrate 110 between the PMOS and the NMOS. As in the example illustrated in FIG. 2, a part of the first circuit 122 may be included in the first supporting substrate 110.

The first via 123 is formed on the first circuit 122, and causes the first circuit 122 to be electrically conducted with the first rewiring layer 130. The second via 127 is formed on the second circuit 125, and causes the second circuit 125 to be electrically conducted with the first rewiring layer 130.

The first rewiring layer 130 is formed on the first circuit layer 120. The first rewiring layer 130 includes an electrode pad 131, an electrode pad 133, and a wiring 135, formed of a conductive material such as copper. The first rewiring layer 130 is formed by depositing an insulative material such as silicon on the first circuit layer 120, excluding the metal element such as the electrode pad 131.

The electrode pad 131 is formed on the first via 123 of the first circuit layer 120, and is electrically conducted with the first circuit 122 via the first via 123. The electrode pad 133 is formed on the second via 127 of the first circuit layer 120, and is electrically conducted with the second circuit 125 via the second via 127. The wiring 135 is connected to the electrode pad 131 and the electrode pad 133, and causes the second circuit 125 of the first circuit layer 120 to be electrically conducted with the first circuit 122.

The second semiconductor chip 200 has a second supporting substrate 210, a second circuit layer 220, a second rewiring layer 230, and the first embedded portion 240 and the first through via 250 described above. The second supporting substrate 210 is bonded to the first circuit layer 120 side of the first semiconductor chip 100. Similarly to the first supporting substrate 110, the second supporting substrate 210 is a silicon substrate, for example. The second supporting substrate 210 may be made thinner than the first supporting substrate 110 by being thinned before being bonded to the first semiconductor chip 100, and may have a thickness of approximately 5 μm, for example.

The second circuit layer 220 is formed on a surface in the second supporting substrate 210 on an opposite side from the first semiconductor chip 100. The second circuit layer 220 includes the third region 221 and the fourth region 224 on which the second circuit 225 is formed, as described above. The second circuit layer 220 further includes a second via 227 formed of a conductive material such as copper. The second circuit layer 220 is formed by depositing an insulative material such as silicon on the second supporting substrate 210, excluding the second circuit 225 or an metal element such as the second via 227, and has a thickness of approximately 5 to 50 μm. Note that, the second circuit layer 220 may be bonded to the second supporting substrate 210 via an adhesive layer.

As can be understood from FIG. 1 and FIG. 2, the second semiconductor chip 200 may have the same structure as the first semiconductor chip 100, except that it is stacked on the first semiconductor chip 100 and that the second semiconductor chip 200 does not have the first circuit 222 in the third region 221. Therefore, the third region 221 of the second circuit layer 220 in the second semiconductor chip 200 corresponds to a position of the first region 121 of the first circuit layer 120 in the first semiconductor chip 100, and the fourth region 224 of the second circuit layer 220 in the second semiconductor chip 200 corresponds to a position of the second region 124 of the first circuit layer 120 in the first semiconductor chip 100.

The second circuit 225 is formed on the second supporting substrate 210. The second via 227 is formed on the second circuit 225, and causes the second circuit 225 to be electrically conducted with the second rewiring layer 230.

The second rewiring layer 230 is formed on the second circuit layer 220. The second rewiring layer 230 includes an electrode pad 231, an electrode pad 233, and wiring 235, formed of a conductive material such as copper. The second rewiring layer 230 is formed by depositing an insulative material such as silicon on the second circuit layer 220, excluding a metal element such as the electrode pad 231.

The electrode pad 231 is formed on the first through via 250, and is electrically conducted with the first circuit 122 of the first semiconductor chip 100 via the first through via 250 or the like. The electrode pad 233 is formed on the second via 227 of the second circuit layer 220, and is electrically conducted with the second circuit 225 via the second via 227. The wiring 235 is connected to the electrode pad 231 and the electrode pad 233, and causes the second circuit 225 of the second circuit layer 220 to be electrically conducted with the first through via 250.

The first embedded portion 240 is a portion that is embedded in the first hole portion 241 penetrating through the third region 221 of the second circuit layer 220 and extending to the inside of the second supporting substrate 210, and is formed of an insulative material such as silicon oxide, for example. As illustrated in FIG. 2, the first hole portion 241 does not penetrate through the second supporting substrate 210, and thus, when embedding, in the first hole portion 241, the insulative material to form the first embedded portion 240, the insulative material does not leak from the second supporting substrate 210. The contour of the cross section of the first embedded portion 240 in the stack direction may be round, and may have a diameter of approximately 100 μm for example. The first embedded portion 240 may also have a depth of approximately 10 μm in the stack direction.

The first through via 250 penetrates through the first embedded portion 240 and the second supporting substrate 210. The first through via 250 is landed on the electrode pad 131 that is formed in the first rewiring layer 130. That is, the first through via 250 is electrically conducted with the first circuit 122 of the first circuit layer 120.

Similarly to the first embedded portion 240, the contour of the cross section in the stack direction of the first through via 250 may be round. The diameter of said cross section of the first through via 250 may be approximately 10 μm. The height of the first through via 250 in the stack direction may be approximately 10 to 100 μm. Said height of the first through via 250 can be lowered to approximately 10 μm by making the second supporting substrate 210 to be thinner than the first supporting substrate 110, as described above. In this manner, performance degradation of the stacked chip 10 due to parasitic capacitance or parasitic resistance of the first through via 250 can be reduced. Note that, the first through via 250 may have larger cross-section area or height in the stack direction than the via inside each semiconductor chip such as the first via 123, the second via 127, the second via 227 or the like.

Note that, in FIG. 2, only some of the components in the schematic configuration diagram of the stacked chip 10 in FIG. 1 are schematically illustrated, and illustration of other components are omitted. For example, the first circuit 122A among the first circuit 122 of the first semiconductor chip 100 needs to input/output signals with a device external to the stacked chip 10 via the first via 123 and the electrode pad 131, and the external device is implemented on another circuit substrate together with the stacked chip 10, for example. In this case, since the first supporting substrate 110 of the first semiconductor chip 100 is implemented on said circuit substrate, the first rewiring layer 130 including the electrode pad 131 may be electrically conducted with the external device via another TSV that penetrates through the first circuit layer 120 and the first supporting substrate 110 and another electrode pad that is formed on an end of said TSV exposed on the lower surface of the first supporting substrate 110.

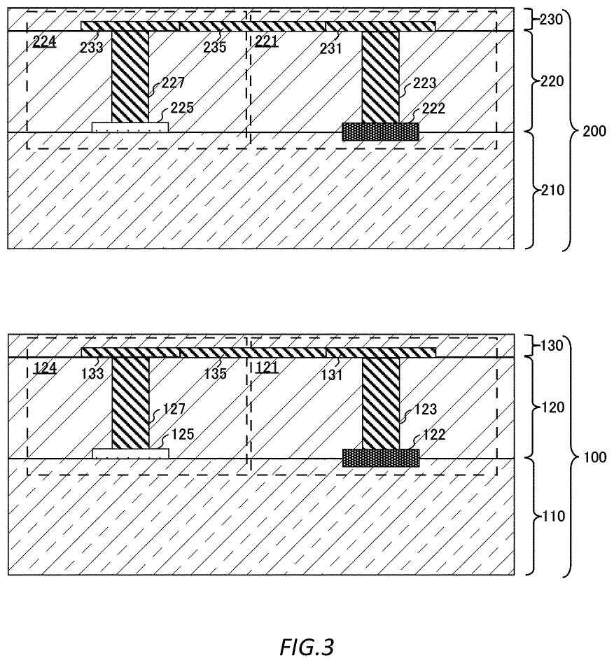

FIG. 3 to FIG. 10 are schematic cross-sectional view illustrating examples of a fabrication method of the stacked chip 10 according to the first embodiment. In the description of the fabrication method of the stacked chip 10, the semiconductor chip that is the precursor of the second semiconductor chip 200, as described above, is also referred to as the second semiconductor chip 200.

The fabrication method of the stacked chip 10 comprises preparing the first semiconductor chip 100 and the second semiconductor chip 200, each having at least two types of circuit formed at a predetermined position, as illustrated in FIG. 3. More specifically, the fabrication method of the stacked chip 10 comprises preparing a first semiconductor chip 100 having a first supporting substrate 110 and a first circuit layer 120 that is formed on the first supporting substrate 110, and includes a first region 121 on which the first circuit 122 is formed and a second region 124 on which the second circuit 125 is formed. The fabrication method of the stacked chip 10 also comprises preparing the second semiconductor chip 200 having a second supporting substrate 210, and a second circuit layer 220 that is formed on the second supporting substrate 210, and that includes a third region 221 on which the first circuit 222 is formed and a fourth region 224 on which the second circuit 225 is formed.

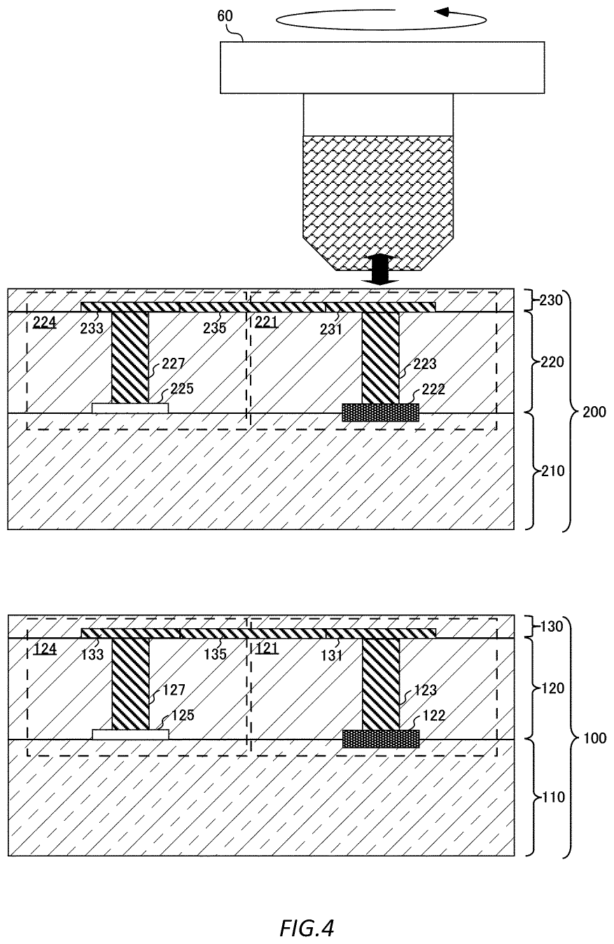

As illustrated in FIG. 4 to FIG. 6, the fabrication method of the stacked chip 10 comprises removing one of the at least two types of circuit described above by forming a first hole portion 241 in the second semiconductor chip 200, and forming a first embedded portion 240 that is embedded in the first hole portion 241. More specifically, the fabrication method of the stacked chip 10 comprises removing the first circuit 222 of the second circuit layer 220 in the second semiconductor chip 200 to form the first hole portion 241 penetrating through the third region 221 of the second circuit layer 220 and extending to an inside of the second supporting substrate 210, and forming the first embedded portion 240 that is embedded in the first hole portion 241.

The first circuit 222 of the second circuit layer 220 may be destroyed and removed by being mechanically polished by a first polishing machine 60, as in the example illustrated in FIG. 4. The blade cutting edge of the first polishing machine 60 has a shape that is complementary to that of the first hole portion 241, and is pressed to the second rewiring layer 230 side of the second semiconductor chip 200 while rotating, as illustrated with an arrow in FIG. 4, to cut the second semiconductor chip 200 to a predetermined depth. As described above, a part of the first circuit 222 may be formed near the surface of the second supporting substrate 210. Therefore, said depth may be a depth that is necessary and sufficient to completely destroy and remove the first circuit 222 of the second circuit layer 220 but not penetrate through the second supporting substrate 210. Said depth is approximately 10 μm, for example, similarly to the depth in the stack direction of the first embedded portion 240. Note that, instead of mechanical polishing, the first circuit 222 of the second circuit layer 220 may be destroyed and removed by CMP (chemical mechanical polishing), etching, milling or the like, or may be destroyed and removed by reverse sputtering with ion.

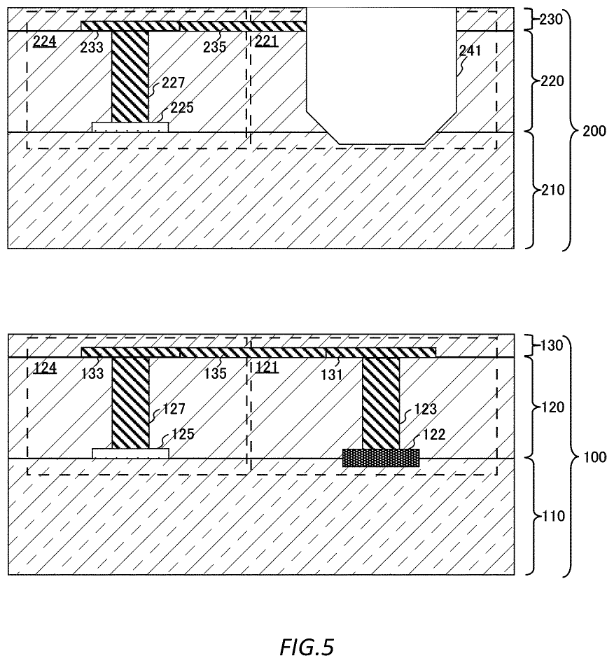

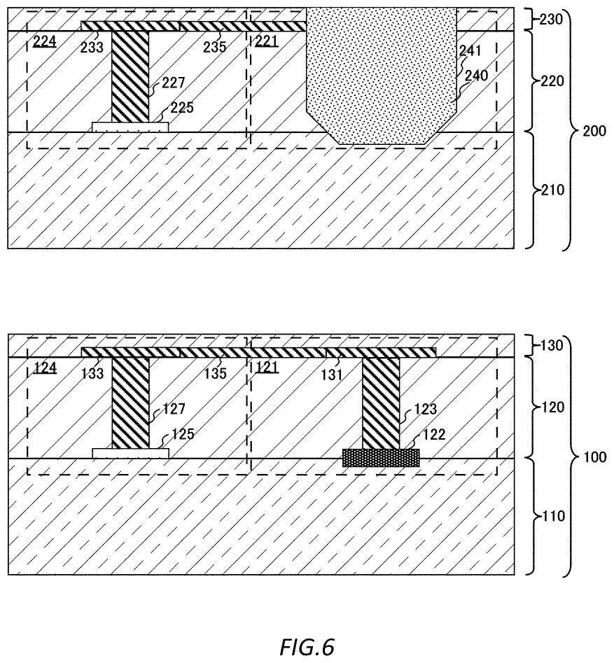

The first embedded portion 240 illustrated in FIG. 6 may be formed by injecting gas to the inside of the first hole portion 241 illustrated in FIG. 5 to deposit a insulating film such as silicon oxide thereon, and planarizing it with CMP. Before forming an insulating film inside the first hole portion 241, the residue of silicon or the like remaining inside the first hole portion 241 may be removed by etching.

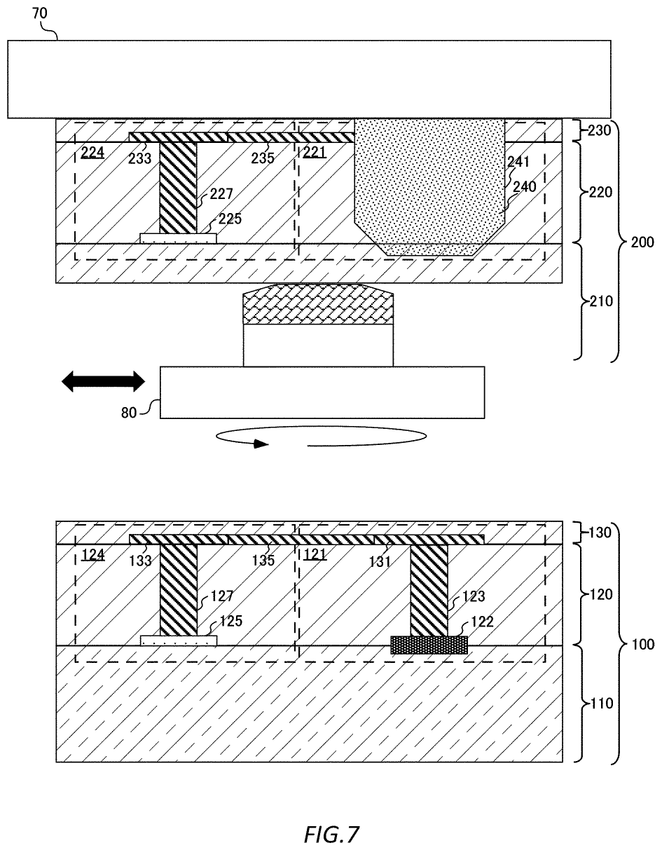

As illustrated in FIG. 7, the fabrication method of the stacked chip 10 may comprise thinning the second supporting substrate 210 in the second semiconductor chip 200 from the lower surface side with a second polishing machine 80, with the second circuit layer 220 side in the second semiconductor chip 200, that is, the second rewiring layer 230 being retained by a retaining portion 70 having means such as a vacuum chuck. The second supporting substrate 210 may have a thickness of approximately 700 μm before the thinning. The thickness of the second supporting substrate 210 may become approximately 5 μm after the thinning. Note that, the second polishing machine 80 moves along the Lower surface of the second supporting substrate 210 while rotating with its blade cutting edge pressed against the lower surface side of the second supporting substrate 210, as illustrated with an arrow in FIG. 7, for example.

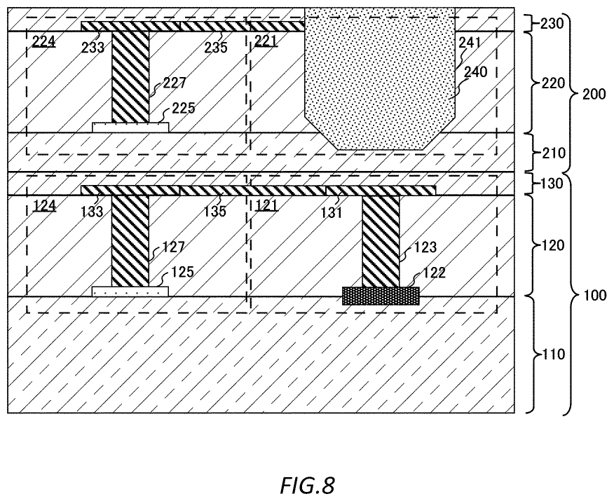

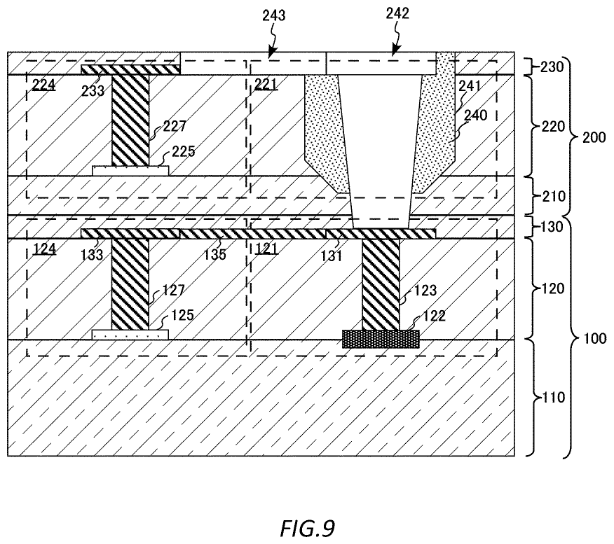

The fabrication method of the stacked chip 10 comprises bonding the first semiconductor chip 100 and the second semiconductor chip 200 together, as illustrated in FIG. 8. More specifically, the fabrication method of the stacked chip 10 comprises bonding the second supporting substrate 210 of the second semiconductor chip 200 to the first circuit layer 120 side of the first semiconductor chip 100, that is, the first rewiring layer 130. The second semiconductor chip 200 may be bonded to the first semiconductor chip 100 with the second circuit layer 220 side, that is, the second rewiring layer 230 being retained by the retaining portion 70 illustrated in FIG. 7. The fabrication method of the stacked chip 10 may comprise forming a through hole 242 that penetrates through the first embedded portion 240 and the second supporting substrate 210 and reaches above the electrode pad 131 in the first rewiring layer 130 of the first semiconductor chip 100, in the second semiconductor chip 200, as illustrated in FIG. 9. The fabrication method of the stacked chip 10 may also comprise forming a groove 243 that extends from a position where the first through via 250 is formed in the first embedded portion 240 to right above the second circuit 225, that is, the electrode pad 233, in the second semiconductor chip 200, as illustrated in FIG. 9. In other words, the fabrication method of the stacked chip 10 may comprise forming the groove 243 that extends on the second rewiring layer 230 from an end on the second rewiring layer 230 side of the through hole 242 to the electrode pad 233. The through hole 242 and the groove 243 may be formed by etching using a mask pattern, for example.

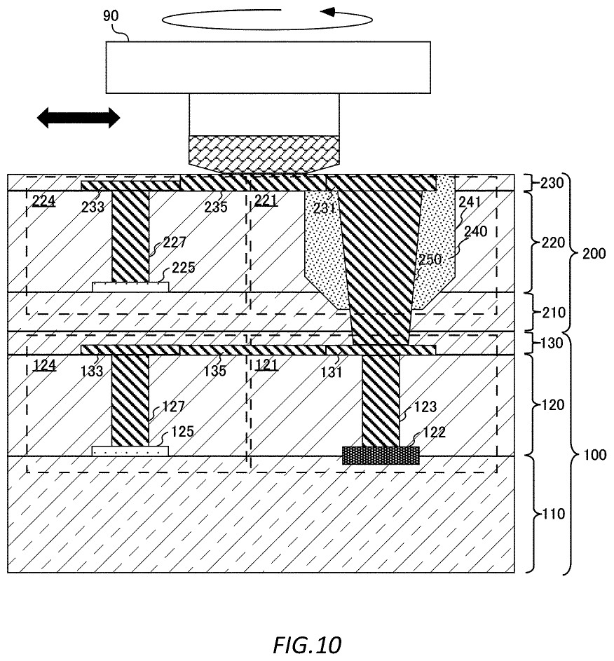

The fabrication method of the stacked chip 10 comprises forming a first through via 250 that penetrates through the first embedded portion 240, and causing the remaining circuit in the second semiconductor chip 200 to be electrically conducted with at least one circuit of the at least two types of circuits described above in the first semiconductor chip 100 via the first through via 250, as illustrated in FIG. 10. Said at least one circuit is the circuit that corresponds to a position of the circuit having been removed in the second semiconductor chip 200.

More specifically, the fabrication method of the stacked chip 10 comprises forming a first through via 250 that penetrates through the first embedded portion 240 and the second supporting substrate 210 in the second semiconductor chip 200, and causing the second circuit 225 in the second semiconductor chip 200 to be electrically conducted with the first circuit 122 in the first semiconductor chip 100 via the first through via 250. The first circuit 122 is the circuit that corresponds to a position of the first circuit 222 having been removed in the second semiconductor chip 200.

The first through via 250 may be formed by filling the inside of the through hole 242 with electroplate such as copper, after performing plating with the use of a seed layer on the inner wall of the through hole 242 by sputtering, for example. The end on the second rewiring layer 230 side of the first through via 250 may be planarized by removing excess portion of the electroplate that may be attached to the surface of the second rewiring layer 230 together with the surface of the second rewiring layer 230 by means of CMP using a third polishing machine 90, as illustrated in FIG. 10. The first through via 250 is landed on the electrode pad 131 by being formed inside the through hole 242 that reaches above the electrode pad 131 in the first rewiring layer 130 of the first semiconductor chip 100. Note that, the third polishing machine 90 moves along the surface of the second rewiring layer 230 while rotating with its blade cutting edge pressed against the surface of the second rewiring layer 230, as illustrated with an arrow in FIG. 10, for example.

Causing the second circuit 225 to be electrically conducted with the first circuit 122, as described above, may include forming an additional wiring 235 embedded in the groove 243, together with the first through via 250, and causing the second circuit 225 in the second semiconductor chip 200 to be electrically conducted with the first through via 250 via the additional wiring 235. The additional wiring 235 and the first through via 250 may be formed together by means of damascene method.

The stacked chip 10 according to the first embodiment describe above comprises a first semiconductor chip 100 and a second semiconductor chip 200 bonded to the first semiconductor chip 100, and a first through via 250 is formed in a region in which a circuit that is not used in the second semiconductor chip 200, for example a circuit that corresponds to a circuit specific to the first semiconductor chip 100 has been destroyed and removed. In this manner, an unwanted circuit region in the second semiconductor chip 200 can be utilized as a region for TSV.

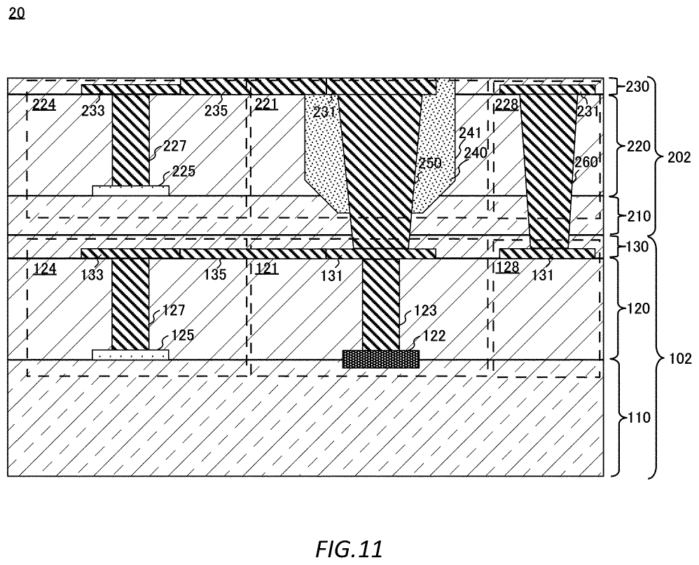

FIG. 11 is a schematic cross-sectional view of the stacked chip 20 according to the second embodiment. As a difference from the stacked chip 10 according to the first embodiment, in the stacked chip 20, the first circuit layer 120 of the first semiconductor chip 102 includes an additional region 128 other than the first region 121 and the second region 124, and similarly, the second circuit layer 220 of the second semiconductor chip 202 includes an additional region 228 other than the third region 221 and the fourth region 224. Since the other components in the stacked chip 20 is similar to those in the stacked chip 10 according to the first embodiment, reference numerals similar to those for each component of the stacked chip 10 is provided, and duplicate description will be omitted. Note that, duplicate description will be similarly omitted in other embodiments below.

In the first rewiring layer 130 of the first semiconductor chip 102, an electrode pad 131 is formed at a position that corresponds to the additional region 128 in the first circuit layer 120. The second semiconductor chip 202 has an additional through via 260 that penetrates through the additional region 228 of the second circuit layer 220 and the second supporting substrate 210 and that is electrically conducted with the first circuit 122 of the first circuit layer 120 via said electrode pad 131 formed on the first rewiring layer 130 of the first semiconductor chip 100. The second semiconductor chip 202 may have one or more of such additional through vias 260. In the second rewiring layer 230 of the second semiconductor chip 202, an electrode pad 231 that is connected to the end of each of the one or more additional through vias 260 is formed, and each electrode pad 231 is electrically conducted with the second circuit 225 via the wiring 235 and the second via 227. Therefore, the stacked chip 20 causes the second circuit 225 of the second semiconductor chip 202 to be electrically conducted with the first circuit 122 of the first semiconductor chip 102 via not only the first through via 250 but also via the one or more additional through vias 260.

The stacked chip 20 according to the second embodiment comprising such configuration has an effect similar to that of the stacked chip 10 according to the first embodiment. Also with the stacked chip 20 according to the second embodiment, parallelism at the time when the first circuit 122 of the first semiconductor chip 102 reads the signal from the second circuit 125 of the second semiconductor chip 202 can be increased, and the width of the data bus can be widened.

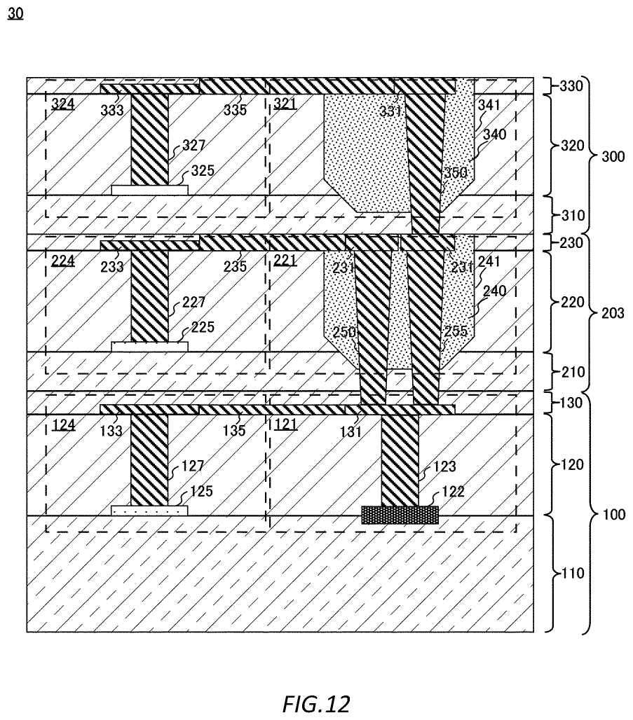

FIG. 12 is a schematic cross-sectional view of the stacked chip 30 according to the third embodiment. As a difference from the stacked chip 10 according to the first embodiment, the stacked chip 30 further comprises a third semiconductor chip 300 bonded to the second semiconductor chip 203, and the second semiconductor chip 203 further has a third through via 255 for causing the second circuit 325 of the third semiconductor chip 304 to be electrically conducted with the first circuit 122 of the first semiconductor chip 100.

The third semiconductor chip 300 is a slave memory die, similarly to the second semiconductor chip 203. Since the third semiconductor chip 300 comprises a configuration that corresponds to that of the second semiconductor chip 200 of the stacked chip 10 according to the first embodiment, duplicate detailed description will be omitted in the following.

The third semiconductor chip 300 has a third supporting substrate 310, a third circuit layer 320, a third rewiring layer 330, a second embedded portion 340, and a second through via 350. The third supporting substrate 310 is bonded to the second circuit layer 220 side of the second semiconductor chip 203. The third circuit layer 320 is formed on a surface in the third supporting substrate 310 on an opposite side from the second semiconductor chip 203. The third circuit layer 320 includes a fifth region 321 that corresponds to a position of the first region 121 of the first circuit layer 120 in the first semiconductor chip 100, and a sixth region 324 that corresponds to a position of the second region 124 of the first circuit layer 120 and on which the second circuit 325 is formed.

The third rewiring layer 330 includes an electrode pad 331, an electrode pad 333, and a wiring 335. The electrode pad 333 is connected to the second circuit 325 via the second via 327 in the sixth region 324 of the third circuit layer 320. The wiring 335 causes the second circuit 325 of the third circuit layer 320 to be electrically conducted with the second through via 350 via the second via 327, the electrode pad 331, and the electrode pad 333.

The second embedded portion 340 is embedded in the second hole portion 341 that penetrates through the fifth region 321 of the third circuit layer 320 and that extends to the inside of the third supporting substrate 310. The second through via 350 penetrates through the second embedded portion 340 and the third supporting substrate 310. The second through via 350 is landed on the electrode pad 231 of the second rewiring layer 230 in the second semiconductor chip 203.

Similarly to the first through via 250, the third through via 255 of the second semiconductor chip 203 penetrates through the second circuit layer 220 and the second supporting substrate 210, and is electrically conducted with the first circuit 122 of the first circuit layer 120 of the first semiconductor chip 100. The third through via 255 is landed on the electrode pad 131 of the first rewiring layer 130 in the first semiconductor chip 100. The third through via 255 is formed at a position that corresponds to a position of the second through via 350 of the third semiconductor chip 300, and is also electrically conducted with the second through via 350.

The stacked chip 30 according to the third embodiment comprising such configuration has an effect that is similar to that of the stacked chip 10 according to first embodiment. Note that, when stacking two or more layers of slave memory die for a master memory die, as in the stacked chip 30 according to the third embodiment, it is formed by extending a separate TSV for each slave memory die from the master memory die. Note that, when the TSV to be extended from the master memory die to each slave memory die is connected to the data bus of each slave memory die, the TSV may be shared among the two or more layers of slave memory die.

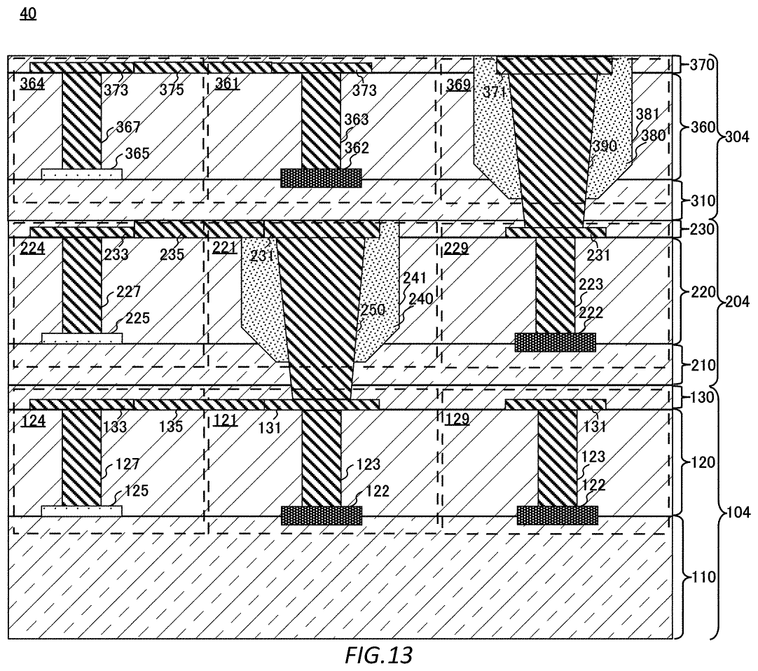

FIG. 13 is a schematic cross-sectional view of the stacked chip 40 according to the fourth embodiment. As a difference from the stacked chip 10 according to the first embodiment, the stacked chip 40 further comprises a third semiconductor chip 304 that is bonded to the second semiconductor chip 204, and the first semiconductor chip 104 has two first circuits 122 formed thereon, and the second semiconductor chip 204 also has one first circuit 222 formed thereon. In the stacked chip 40 according to the fourth embodiment, all of the first semiconductor chip 104, the second semiconductor chip 204 and the third semiconductor chip 304 are a master memory die, and input/output a signal with the outside of the stacked chip 40. Note that, except for the first semiconductor chip 104, which is at the bottom layer, one of the two first circuits 222, 362 originally formed on each of the second semiconductor chip 204 and the third semiconductor chip 304 is destroyed and removed to be utilized for TSV.

The first circuit layer 120 of the first semiconductor chip 104 includes a seventh region 129, other than the first region 121 and the second region 124, on which the first circuit 122 is formed. The first circuit 122 in the seventh region 129 is configured in a manner similar to that of the first circuit 122 in the first region 121, and duplicate description will be omitted.

The second circuit layer 220 of the second semiconductor chip 204 includes an eighth region 229, other than the third region 221 and the fourth region 224, that corresponds to a position of the seventh region 129 of the first circuit layer 120 and on which the first circuit 222 is formed. The first circuit 222 in the eighth region 229 is connected to the electrode pad 231 and the wiring 235 of the second rewiring layer 230 via the first via 223 of the second circuit layer 220, thereby being electrically conducted with the second circuit 225 of the fourth region 224.

The third semiconductor chip 304 has a third supporting substrate 310, a third circuit layer 360, a third rewiring layer 370, a third embedded portion 380, and a fourth through via 390. Since the third semiconductor chip 304 comprises a configuration that is similar to the second semiconductor chip 200 of the stacked chip 10 according to the first embodiment at least in part, duplicate detailed description will be omitted in the following.

The third supporting substrate 310 is bonded to the second circuit layer 220 side of the second semiconductor chip 204. The third circuit layer 360 includes a ninth region 361, a tenth region 364, and an eleventh region 369. The ninth region 361 corresponds to the position of the first region 121 of the first circuit layer 120 in the first semiconductor chip 104, and has the first circuit 362 formed thereon. The tenth region 364 corresponds to the position of the second region 124 of the first circuit layer 120 in the first semiconductor chip 104, and has the second circuit 365 formed thereon. The eleventh region 369 corresponds to the position of the seventh region 129 of the first circuit layer 120 in the first semiconductor chip 104.

The third rewiring layer 370 includes an electrode pad 371, an electrode pad 373, and a wiring 375. The electrode pad 373 is connected to the second circuit 365 via the second via 367 in the tenth region 364 of the third circuit layer 360. The electrode pad 373 is also connected to the first circuit 362 via the first via 363 in the ninth region 361 of the third circuit layer 360. The electrode pad 371 is connected to the fourth through via 390 in the eleventh region 369 of the third circuit layer 360. The wiring 375 causes the second circuit 365 of the third circuit layer 320 to be electrically conducted with each of the fourth through via 390 and the first circuit 362 via the electrode pad 371 and the electrode pad 373.

The third embedded portion 380 is embedded in a third hole portion 381 that penetrates through the eleventh region 369 of the third circuit layer 320 and that extends to the inside of the third supporting substrate 310. The fourth through via 390 penetrates through the third embedded portion 380 and the third supporting substrate 310, and is electrically conducted with the first circuit 222 of the second circuit layer 220 of the second semiconductor chip 204. The fourth through via 390 is landed on the electrode pad 231 of the second rewiring layer 230 in the second semiconductor chip 204.

The stacked chip 40 according to the fourth embodiment comprising such configuration has an effect similar to that of the stacked chip 10 according to the first embodiment. The stacked chip 40 according to the fourth embodiment may be utilized when increasing the bus width as compared to a single semiconductor chip by using the first circuits 222, 362 of the second semiconductor chip 204 and the third semiconductor chip 304 together with the two first circuits 122 of the first semiconductor chip 104, for example, so that the stacked chip 40 as a whole functions as a combined master memory die. In this case, the stacked chip 40 destroys and removes the first circuit 222, 362 that is not used, among the two first circuits 222, 362 originally formed in each of the second semiconductor chip 204 and the third semiconductor chip 304, to be utilized for TSV.

Among the plurality of embodiments described above, in the stacked chip according to the first embodiment to the third embodiment, a configuration in which the master memory die is stacked at the bottom layer has been described. Instead of this, in the stacked chip, the master memory die may be stacked on the top layer. The stacked chip in this case comprises at least two slave memory dies below the master memory die, where the slave memory die directly below the master memory die may be considered as the second semiconductor chip described above, and the slave memory die directly below said slave memory die may be considered as the first semiconductor chip described above. The master memory die at the top layer has a TSV formed thereon that causes the first circuit that is a control circuit of the master memory die and the second circuit that is the memory circuit of the slave memory die, that is at least directly below thereof, to be electrically conducted with each other.

In the plurality of embodiments described above, the stacked chip has been described as a stacked-type dynamic memory, but it is not limited thereto, and may be, for example, an MPU (micro-processing unit), a GPU (graphics processing unit), a FPGA (field-programmable gate array) or the like.

While the present invention has been described with the embodiments, the technical scope of the present invention is not limited to the above-described embodiments. It is apparent to persons skilled in the art that various alterations and improvements can be added to the above-described embodiments. It is also apparent from the description of the claims that the embodiments to which such alterations or improvements are made can be included in the technical scope of the present invention.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: stacked chip,
100: first semiconductor chip,
110: first supporting substrate,
120: first circuit layer,ci
121: first region,
122, 122A, 122B, 122C: first circuit,
123: first via,
124: second region,
125: second circuit,
126: data path,
127: second via,
130: first rewiring layer,
131, 133: electrode pad,
135: wiring,
200: second semiconductor chip,
210: second supporting substrate,
220: second circuit layer,
221: third region,
222A, 2228, 222C: first circuit,
223: first via,
224: fourth region,
225: second circuit,
226: data path,
227: second via,
230: second rewiring layer,
231, 233: electrode pad,
235: wiring,
240: first embedded portion,
241: first hole portion,
242: through hole,
243: groove,
250: first through via,
60: first polishing machine,
70: retaining portion,
80: second polishing machine,
90: third polishing machine,
20: stacked chip,
102: first semiconductor chip,
128: additional region,
202: second semiconductor chip,
228: additional region,
260: additional through via,
30: stacked chip,
203: second semiconductor chip,
255: third through via,
300: third semiconductor chip,
310: third supporting substrate,
320: third circuit layer,
321: fifth region,
324: sixth region,
325: second circuit,
327: second via,
330: third rewiring layer,
331, 333: electrode pad,
335: wiring,
340: second embedded portion,
341: second hole portion,
350: second through via,
40: stacked chip,
104: first semiconductor chip,
129: seventh region,
204: second semiconductor chip,
229: eighth region,
304: third semiconductor chip,
360: third circuit layer,
361: ninth region,
362: first circuit,
363: first via,
364: tenth region,
365: second circuit,
367: second via,
369: eleventh region,
370: third rewiring layer,
371, 373: electrode pad,
375: wiring,
380: third embedded portion,
381: third hole portion,
390: fourth through via.

What is claimed is:

1. A stacked chip comprising:
a first semiconductor chip; and
a second semiconductor chip that is bonded to the first semiconductor chip, wherein
the first semiconductor chip has:
a first supporting substrate; and
a first circuit layer that is formed on the first supporting substrate, including a first region in which a first circuit is formed and a second region in which a second circuit is formed,
the second semiconductor chip has:
a second supporting substrate that is bonded to the first circuit layer side of the first semiconductor chip;
a second circuit layer that is formed on a surface in the second supporting substrate on an opposite side from the first semiconductor chip, including a third region that corresponds to a position of the first region of the first circuit layer and a fourth region that corresponds to a position of the second region of the first circuit layer and in which the second circuit is formed;
a first embedded portion that is embedded in a first hole portion penetrating through the third region of the second circuit layer and extending to an inside of the second supporting substrate; and
a first through via that penetrates through the first embedded portion and the second supporting substrate, and is electrically conducted with the first circuit of the first circuit layer.

2. The stacked chip according to claim 1, wherein the first hole portion does not penetrate through the second supporting substrate.

3. The stacked chip according to claim 1, wherein a contour of a cross section of the first embedded portion in a stack direction is round.

4. The stacked chip according to claim 1, wherein
the first semiconductor chip and the second semiconductor chip has a same structure except that the second semiconductor chip does not have the first circuit in the third region.

5. The stacked chip according to claim 1, wherein
the second circuit of the first circuit layer and the second circuit of the second circuit layer are memory circuit, and
the first circuit of the first circuit layer is interface circuit or decoding circuit, which inputs/outputs a signal or relays a signal between the second circuit of the first circuit layer and the second circuit of the second circuit layer and an outside of the stacked chip.

6. The stacked chip according to claim 1, wherein
the first semiconductor chip has a first rewiring layer including a first wiring that causes the second circuit of the first circuit layer to be electrically conducted with the first circuit, and
the second semiconductor chip has a second rewiring layer including a second wiring that causes the second circuit of the second circuit layer to be electrically conducted with the first through via.

7. The stacked chip according to claim 6, wherein
the first through via is landed on an electrode pad that is formed on the first rewiring layer.

8. The stacked chip according to claim 6, wherein
the second circuit layer further includes an additional region other than the third region and the fourth region, and
the second semiconductor chip further includes one or more additional through via that penetrates through the additional region of the second circuit layer and the second supporting substrate, and is electrically conducted with the first circuit of the first circuit layer via an electrode pad formed in the first rewiring layer.

9. The stacked chip according to claim 1, further comprising a third semiconductor chip that is bonded to the second semiconductor chip, wherein
the third semiconductor chip has:
a third supporting substrate that is bonded to the second circuit layer side of the second semiconductor chip;
a third circuit layer that is formed on a surface in the third supporting substrate on an opposite side from the second semiconductor chip, including a fifth region that corresponds to a position of the first region of the first circuit layer and a sixth region that corresponds to a position of the second region of the first circuit layer and in which the second circuit is formed;
a second embedded portion that is embedded in a second hole portion penetrating through the fifth region of the third circuit layer and extending to an inside of the third supporting substrate; and
a second through via that penetrates through the second embedded portion and the third supporting substrate,
wherein the second semiconductor chip penetrates through the second circuit layer and second supporting substrate at a position corresponding to a position of the second through via, and further includes a third through via that is electrically conducted with the second through via and the first circuit of the first circuit layer.

10. The stacked chip according to claim 1, wherein
the first circuit layer further includes a seventh region on which the first circuit is formed,
the second circuit layer further includes an eighth region that corresponds to a position of the seventh region of the first circuit layer and on which the first circuit is formed,
the stacked chip further comprising a third semiconductor chip bonded to the second semiconductor chip, wherein the third semiconductor chip has:
a third supporting substrate bonded to the second circuit layer side of the second semiconductor chip;
a third circuit layer that is formed in the third supporting substrate on a side opposite from the second semiconductor chip, including a ninth region that corresponds to a position of the first region of the first circuit layer and on which the first circuit is formed, a tenth region that corresponds to a position of the second region of the first circuit layer and in which the second circuit is formed, and an eleventh region that corresponds to a position of the seventh region of the first circuit layer;
a third embedded portion that is embedded in a third hole portion penetrating through the eleventh region of the third circuit layer and extending to an inside of the third supporting substrate; and
a fourth through via that penetrates through the third embedded portion and the third supporting substrate, and is electrically conducted with the first circuit of the second circuit layer.

11. A fabrication method of a stacked chip comprising:
preparing a first semiconductor chip and a second semiconductor chip each having:
a supporting substrate; and
a circuit layer formed on the supporting substrate, including a first region in which a first circuit is formed and a second region in which a second circuit is formed;
removing the first circuit of the circuit layer in the second semiconductor chip to form a hole portion that penetrates the first region of the circuit layer and extends to an inside of the supporting substrate;
forming an embedded portion that is embedded in the hole portion in the second semiconductor chip;
bonding the supporting substrate of the second semiconductor chip to the circuit layer side of the first semiconductor chip; and
forming a through via that penetrates through the embedded portion and the supporting substrate in the second semiconductor chip, and causing the second circuit in the second semiconductor chip to be electrically conducted with the first circuit in the first semiconductor chip corresponding to a position of the first circuit that has been removed in the second semiconductor chip, via the through via.

12. The fabrication method according to claim 11, further comprising thinning the supporting substrate in the second semiconductor chip with the circuit layer side in the second semiconductor chip being retained by a retaining portion, wherein
the bonding includes bonding the supporting substrate of the second semiconductor chip to the circuit layer side of the first semiconductor chip with the circuit layer side in the second semiconductor chip being retained by the retaining portion.

13. The fabrication method according to claim 11 further comprising forming a groove that extends from a position at which the through via is formed to the second circuit in the embedded portion in the second semiconductor chip, wherein
the causing electrical conductivity includes forming, together with the through via, an additional wiring that is embedded in the groove, and causing the second circuit in the second semiconductor chip to be electrically conducted with the through via the additional wiring.

14. A fabrication method of a stacked chip comprising:
preparing a first semiconductor chip and a second semiconductor chip, each having at least two types of circuit formed at a predetermined position;
removing one of the at least two types of circuit by forming a hole portion in the second semiconductor chip, to form an embedded portion that is embedded in the hole portion;
bonding the first semiconductor chip and the second semiconductor chip together; and
forming a through via that penetrates through the embedded portion in the second semiconductor chip, and causing a remaining circuit in the second semiconductor chip to be electrically conducted with circuit corresponding to a position of the circuit that has been removed in the second semiconductor chip, among the at least two types of circuit in the first semiconductor chip, via the through via.
